(19) United States
(12) Patent Application Publication
(10) Pub. No.: US 2010/0207887 A1
(43) Pub. Date: Aug. 19, 2010

(54) One-handed computer interface device

(76) Inventor: Philip M. Jepsen, Dunedin, FL (US)

Correspondence Address: LITMAN LAW OFFICES, LTD., POST OFFICE BOX 41200, SOUTH STATION, ARLINGTON, VA, 22204, US

(21) Appl. No.: 12/379,244

(22) Filed: Feb. 17, 2009

(51) Int. Cl. G06F 3/02; H03M 11/00

(52) U.S. Cl. 345/168; 341/22

(57) ABSTRACT

The one-handed computer interface device is a computer input device that allows the user to input a full range of computer commands using only one hand. The one-handed computer interface device includes a housing having opposed upper and lower surfaces and at least one side surface. The upper surface of the housing is divided into a plurality of finger regions, with each finger region being adapted for receiving one of the user's fingers. Similarly, a thumb region is further defined on the at least one side surface, with the thumb region being adapted for receiving the user's thumb. A plurality of sets of finger tip sensors and a set of thumb tip sensors are respectively positioned within each finger region and the thumb region. In use, actuation of one of the finger tip and thumb tip sensors generates a command signal corresponding to actuation of a computer key.

### BACKGROUND OF THE INVENTION

1. Field of the Invention

The present invention relates to computer hardware, and particularly to a one-handed computer interface device, such as a keyboard or the like, that is adapted for use by a single hand of the user.

2. Description of the Related Art

Operation of a computer or other processing device typically depends upon a user inputting data or commands via an input device. Various devices are known for inputting data and commands including, for example, keyboards, keypads, mice, trackballs, joysticks, game controllers, voice recognition systems, wired or wireless remote controllers, or other input devices.

Several drawbacks and limitations exist, however, with known input devices. These drawbacks and limitations are often accentuated when individuals afflicted with hand disabilities, repetitive stress injuries, and arthritis attempt to navigate the human-computer interface. With the growing use of computers for communication, entertainment, composition, and information storage, retrieval, and analysis, an injury to even one finger of one hand may significantly impact a person's performance and outlook, both at home and in the work place. Additionally, using a conventional keyboard in conjunction with a separate input device, such as a mouse, takes additional time (as the user must switch from typing to positioning his or her hand on the mouse), and may cause even more severe repetitive stress injuries. Even for people without disabilities, there is need for improvement in the human factors and ergonomics of computer input devices.

Conventional “QWERTY” keyboards, for example, tend to be the industry standard for desktop and portable computers. These keyboards are generally bulky and are principally designed for operation by two hands. With two-handed touch-typing, individuals, on average, may input approximately sixty words per minute. Proficiency with “QWERTY” keyboards typically comes after many weeks of use, but may be significantly diminished by hand disabilities or injuries. Overuse of this type of keyboard is a primary cause of repetitive stress injury of the hands.

Smaller keyboards have been designed, but are often difficult to use, as the size of the keys are often reduced, without changing the overall configuration of the conventional keys, or the keys are arranged in uncomfortable ways. In addition, smaller keyboards generally do not allow effective use by a single hand. Other types of input devices often lack the range of functions that may be realized using full-sized keyboards. Specifically, other input devices have fewer controls for performing limited kinds of operations. Therefore, a need exists for a device which allows inputs of all characters and functions, but which is smaller than a full-size “QWERTY” keyboard, and is easily operable by one hand.

In addition to the smaller keyboards referenced above, various compact keypads have been designed. In general, such compact keypads, including one-handed character input devices, provide some sort of multiplicity for each key comprising the keypad, such that a reduced number of keys can represent a full character set. A common method for obtaining key multiplicity is key-chording. Key-chording uses key combinations, pressed or activated simultaneously or in sequence, to represent characters. A variation of the key-chording technique is the use of a selector switch. The keys on the keypad represent different characters depending upon the current position of the selector switch.

While key-chording provides key multiplicity and allows for a keypad with fewer keys than a full keyboard, it is a complex technique that must be mastered by the user, and which reduces the user's speed, particularly in relation to conventional touch typing. A user must learn which combinations of keys create each character. Furthermore, great precision is required during use to ensure that the sets of keys are pressed simultaneously or in the proper sequence. If keys are not activated simultaneously, an incorrect set of characters may result. Therefore, a need exists for a simple, compact keypad or other interface device that can easily represent all of the characters on an ordinary keyboard.

Another known, but less common, technique for inputting data and commands, is keypad-transplacement. Despite the improvements in keypad design using known keypad-transplacement techniques, various deficiencies exist. In at least some implementations, possible keypad positions are limited along a single axis of rotation or movement, which provides only three possible values for each of the keys. Additionally, a separate trackball or other device may be required for cursor or pointer positioning, or other movement commands in multiple dimensions.

One or more of the foregoing keyboards, keypads, or other input devices may also experience other problems which may limit their use. For example, some input devices are designed to operate with only a specific hand (e.g., the right hand). This may be difficult for left-handed people, or for individuals with disabilities.

In addition, some computer programs often require simultaneous operation of certain keys for additional functionality. For example, the “ctrl,” “alt,” and “shift” keys on an ordinary keyboard, when used in various combinations with other keys, may perform certain functions in various applications such as, for example, Microsoft Word®, produced by the Microsoft Corporation. Some alternative keypads do not include these keys or the possibility of simultaneous operation of such keys.

Furthermore, with many compact keypads, users may have difficulty remembering the combination of keys-, or combinations of position and keys, which generate specific characters or perform specific functions. As with any new input device, extensive practice is required to learn and become familiar with the operation. However, most keypads do not provide effective aids to assist the novice user. Often the characters are solely on the keys, which are covered by the user's fingers during operation.

Some input devices have incorporated thumb or finger scrolls. Such devices simplify scrolling and other functions when viewing documents. Nevertheless, compact keypads typically have not incorporated scroll devices. Additionally, keyboards and keypads are often uncomfortable for users. Incidents of carpal tunnel syndrome have increased in recent years, as people have increasingly used awkward input devices. Various accessories, such as pads and supports, have been developed for computer users to ease the strain on arms, hands, and other body parts that may result from use of conventional keyboards and pads. Nevertheless, a need exists for a keypad or other interface device that provides comfortable support and easy manipulation.

In addition to the foregoing drawbacks and limitations of known keyboards and keypad devices, many computer systems further rely on a second input device (e.g., a pointer device) to navigate the graphical user interfaces of various software applications. A computer “mouse,” for example, is perhaps the most commonly used input device used to effectuate pointer control. Many individuals often rely on both a keyboard or keypad and a mouse to input data and commands. This may be frustrating for certain applications that may require continual switching between a keyboard and a mouse such as, for instance, when creating and/or editing a word processing document. Alternatively, “quick keys” on a keyboard or keypad may be used primarily to avoid a pointer device altogether. Often, pointer devices on portable computers (e.g., laptop computers) are so poor that laptop users learn to become quite proficient with quick keys. Further, many applications require extensive use of a mouse, such as CAD and gaming applications, while also using the full functions of a keyboard. In these applications, the user typically has no option but to frequently switch one hand, back and forth, between the mouse and the keyboard.

As the number of different computing platforms expands, more and more devices are being programmed to provide various functions. Many gaming consoles, for example, now include network (e.g., Internet) connections. Cellular telephones and Personal Digital Assistants (PDA's) also include network connections. As these and other devices and systems are being designed or enhanced, many different control devices are being provided with different functionality. It is not uncommon for a user to need to learn a myriad of interfaces just to control all of his or her electronic devices. Thus, a one-handed computer interface device solving the aforementioned problems is desired.

### SUMMARY OF THE INVENTION

The one-handed computer interface device is a computer input device that allows the user to input a full range of computer commands typically provided by a computer keyboard, but using only one hand. The one-handed computer interface device includes a housing having opposed upper and lower surfaces and at least one side surface, with the upper surface preferably being contoured to ergonomically support the user's palm. The lower surface may be adapted for positioning on a support surface, such as a desktop or the like. It should be understood that other configurations for the housing may be necessary for application to devices other than keyboards, such as cellular telephones and the like. The upper surface of the housing is divided into a plurality of finger regions, with each finger region being adapted for receiving one of the user's fingers. Similarly, a thumb region is further defined on the at least one side surface, with the thumb region being adapted for receiving the user's thumb.

A plurality of sets of finger tip sensors and a set of thumb tip sensors are respectively positioned within each finger region and the thumb region. Each sensor may be any suitable type of finger-actuable sensor, such as mechanical switches or buttons, thermal sensors, pressure sensors, optical sensors or the like. Preferably, each set of finger tip sensors and the set of thumb tip sensors includes a plurality of radially arrayed sensors and a central sensor. Further, each finger region and the thumb region preferably each include a depression, for resting the user's finger tips and thumb tip during use. In use, actuation of one of the finger tip and thumb tip sensors generates a command signal corresponding to actuation of a computer key.

A scrolling controller, such as a track ball, a conventional scroll wheel or the like, may further be mounted on the upper surface, thus allowing the keyboard to include additional functionality, similar to that of a conventional computer mouse. Further, indicia are formed on the upper surface and the at least one side surface adjacent the plurality of finger regions and the thumb region, with the indicia indicating the corresponding computer key for each finger tip and thumb tip sensor.

Preferably, each set of radially arrayed sensors includes eight sensors, thus providing the functionality and options of a conventional 104-key computer keyboard. In one possible arrangement, the thumb tip sensors and the central sensors may correspond to conventional function keys, with the radially arrayed sensors of the finger regions corresponding to conventional character keys.

These and other features of the present invention will become readily apparent upon further review of the following specification and drawings.

### BRIEF DESCRIPTION OF THE DRAWINGS

FIG. 1 is a perspective view of a one-handed computer interface device according to the present invention.

FIG. 2A is a partial plan view of the one-handed computer interface device according to the present invention, illustrating a thumb region thereof.

FIG. 2B is a partial plan view of the one-handed computer interface device according to the present invention, illustrating an index finger region thereof.

FIGS. 3A, 3B, 3C, 3D, 3E, 3F and 3G are tables illustrating character and function representations for the one-handed computer interface device according to the present invention.

Similar reference characters denote corresponding features consistently throughout the attached drawings.

### DETAILED DESCRIPTION OF THE PREFERRED EMBODIMENTS

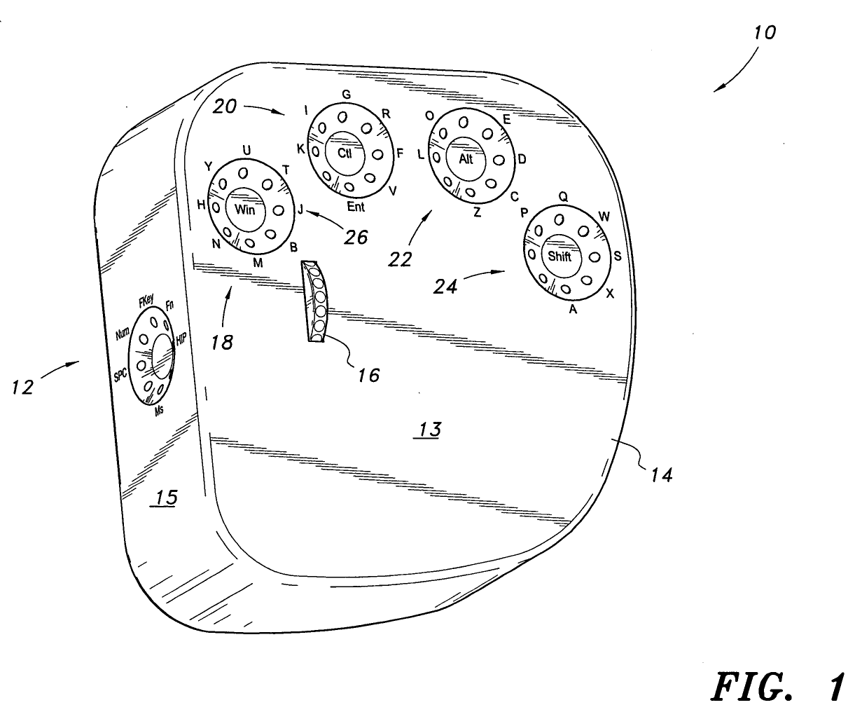

Now referring to FIG. 1, there is shown a one-handed computer interface device 10. The one-handed computer interface device 10 is a computer input device that allows the user to input a full range of computer commands using only one hand. The one-handed computer interface device 10 includes a housing 14 having an upper surface 13 which is preferably contoured to ergonomically support the user's palm, in a manner similar to a conventional mouse-type computer input device. The housing 14 further includes a lower surface adapted for positioning on a support surface, such as a desktop or the like, and at least one side surface 15. It should be understood that the shape and relative dimensions of housing 14 are shown in FIG. 1 for exemplary purposes only. It should be further understood that other configurations for the housing may be necessary for application to devices other than keyboards, such as cellular telephones and the like.

Housing 14 may be formed from plastic or any other suitable material. Interface device 10 communicates with an associated computer or other control-receiving system via cable, wireless interface, or through any other conventional communication, as is well-known in computer keyboards, computer mouse controllers and the like. It should be understood that the controls to be described in detail below may be applied to any input device, such as keyboards, keypads, personal digital assistants, game controllers, cellular telephones, navigations systems, remote controls and the like. Input device 10 is particularly useful in providing an ergonomic, stress and strain-free interface for an electronic device. The one-handed design prevents the causes of stress and strain related injuries, which are common from a conventional QWERTY-style keyboard.

As shown in FIG. 1, the upper surface 13 of the housing 14 is divided into a plurality of finger regions 18, 20, 22, 24, with each finger region being adapted for receiving one of the user's fingers. Preferably, as shown, the finger regions are arrayed to ergonomically match the fingers of a typical user's hand. Finger region 18 receives the finger tip of the user's index finger, finger region 20 receives the finger tip of the user's middle finger, finger region 22 receives the finger tip of the user's ring finger, and finger region 24 receives the finger tip of the user's pinkie finger. It should be understood that the size and contouring of housing 14, along with the positioning of finger regions 18, 20, 22, 24, may be varied to match particular hand sizes and shapes. Similarly, a thumb region 12 is further defined on the at least one side surface 15, with the thumb region 12 being adapted for receiving the user's thumb. In FIG. 1, an interface device for the user's right hand is shown.

As noted above, the keyboard configuration of FIG. 1 is shown for exemplary purposes only. The present invention may be applied to any suitable type of interface, such as those associated with cellular telephones, personal digital assistants, game controllers and the like. It should be understood that an interface device with the positioning of finger regions 18, 20, 22, 24 and thumb region 12 reversed may be provided for use with the user's left hand. It should be understood that FIG. 1 illustrates only an exemplary embodiment. In other devices, such as cellular telephones, personal digital assistants, MP3 players and the like, the thumb and finger regions may be placed anywhere on the device, depending upon the preferred ergonomic placement of the fingers and thumb with such a device. For example, with some handheld devices, the thumb and/or finger regions may be positioned on the rear of the device.

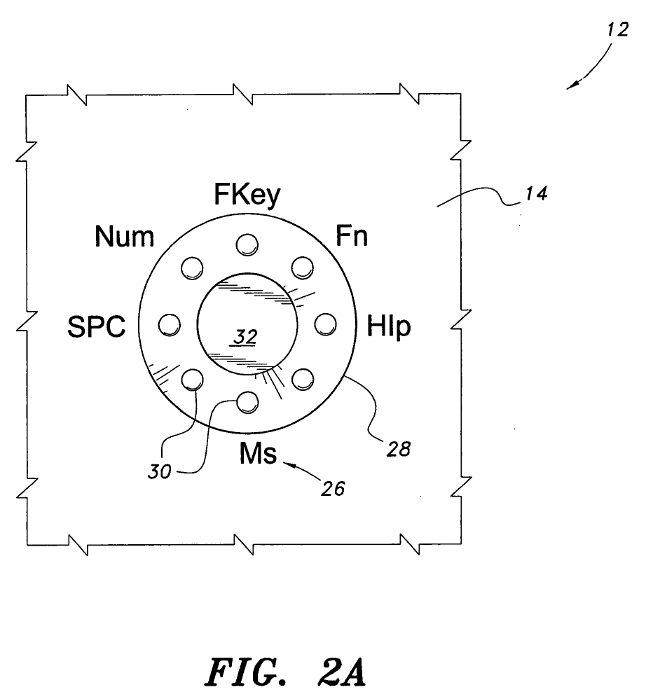

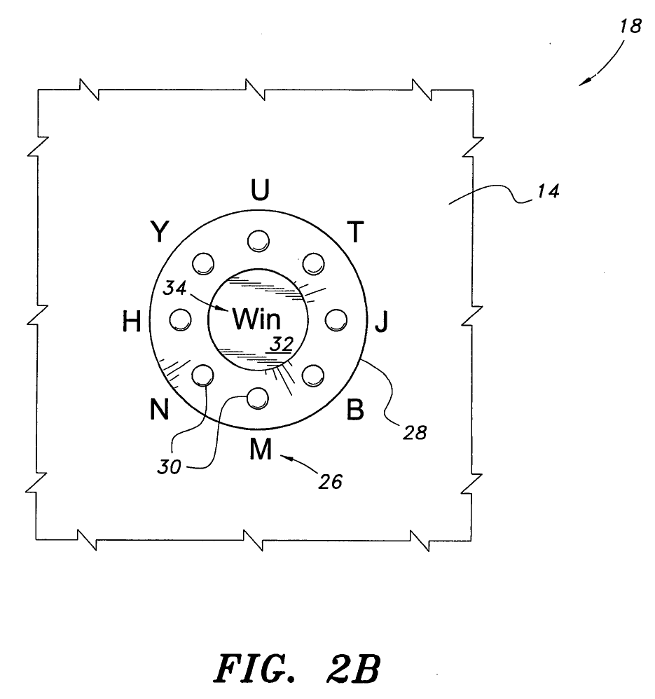

As best shown in FIGS. 2A and 2B, a plurality of sets of finger tip sensors and a set of thumb tip sensors 30 are respectively positioned within each finger region and the thumb region. Each sensor 30 may be any suitable type of finger-actuable sensor, such as mechanical switches or buttons, thermal sensors, capacitance sensors, optical sensors, pressure sensors or the like, which detect pressure or movement of the user's fingers. Preferably, each set of finger tip sensors and the set of thumb tip sensors 30 includes a plurality of radially arrayed sensors, with sensors 30 being approximately evenly spaced, as shown, and a central sensor 32. Central sensor 32 also may be any suitable type of finger-actuable sensor, such as a mechanical switch, a button, a thermal sensor, a capacitance sensor or the like. Further, each finger region and the thumb region preferably each include a depression 28, for resting the user's finger tips and thumb tip during use.

In use, actuation of one of the finger tip and thumb tip sensors 30, 32 generates a command signal corresponding to actuation of a computer key. Command signals are generated in a manner similar to that of signal-generation in a conventional computer keyboard or interface, as is well-known in the art of computer input devices. In addition to that shown, the finger and thumb sensors 30 may be activated by a raised button or joystick-type control, which can be pushed in up to eight different directions, and can further detect central pressure.

A scrolling controller, such as a track ball, a conventional scroll wheel or the like, may further be mounted on the upper surface 13 (with an exemplary scroll wheel 16 being shown in FIG. 1), thus allowing the interface device 1 0 to include additional functionality, similar to that of a conventional computer mouse. Further, indicia 26 are formed on the upper surface 13 and the at least one side surface 15 adjacent the plurality of finger regions and the thumb region, with the indicia 26 indicating the corresponding computer key (i.e., the character or function associated with a conventional computer key of a conventional keyboard) for each finger tip and thumb tip sensor 30. FIG. 2A illustrates an exemplary array of key functions for the user's thumb to actuate, and FIG. 2B illustrates an exemplary array of key functions for the user's index finger to actuate. Although only the index finger region 18 is illustrated, it should be understood that the other finger regions 20, 22, 24 operate in a manner similar to that described with regard to exemplary index finger region 18 illustrated in FIG. 2B. Preferably, each set of radially arrayed sensors 30 includes eight sensors, thus providing the functionality and options of a conventional 104-key computer keyboard. In one possible arrangement, the thumb tip sensors and the central sensors 32 may correspond to conventional function keys, with the radially arrayed sensors 30 of the finger regions 18, 20, 22, 24 corresponding to conventional character keys.

It should be understood that sensors 30 and 32 may be set by the user to correspond to any desired function or character, and that the arrangement and key correspondence shown in FIGS. 1, 2A and 2B is shown for exemplary purposes only. As best shown in FIG. 2A, the central sensor 32 remains unassigned (though may be assigned by the user for any desired user-defined function or character), and as indicia 26 indicate, arrayed sensors 30 are actuable to represent an “F” key (corresponding to a general numeric F-type function key of a conventional computer keyboard); an Fn key (allowing for other computer-related functions, including miscellaneous user-defined functions, as will be described in detail below); an Hip key (corresponding to a general help command); an Ms key (allowing the interface device 10 to function in a manner similar to a mouse-type interface); a Spc key (corresponding to a conventional keyboard spacebar); and a Num key (operating in a manner similar to a number lock key on a conventional keyboard).

FIG. 2B illustrates finger region 18 in detail. As noted above, the other finger regions 20, 22, 24 operate in a similar manner, and region 18 is shown here for illustrative purposes. Central sensor 32 of finger region 18 includes separate indicia 34, denoting that sensor 32 may be actuated, corresponding to a “Windows” key on a conventional keyboard. As shown in FIG. 1, finger region 20 includes a central “Ctl” key (corresponding to a conventional control key); finger region 22 includes a central “Alt” key (corresponding to a conventional Alt key); and finger region 24 includes a central “Shift” key (corresponding to the shift key on a conventional keyboard). As noted above, the indicia 34 and the selected function for each central sensor 32 is user-defined, and those shown in the Figures are shown for exemplary purposes only.

The radially arrayed sensors in region 18 correspond to conventional character keys of a QWERTY-type keyboard, as indicated by indicia 26. In this particular example, the eight sensors represent “Y”, “U”, “T”, “J”, “B”, “M”, “N”, and “H” keys of a conventional keyboard. As noted above, the indicia 26 and the selected function or character for each radially arrayed sensor 30 is user-defined, and those shown in the Figures are shown for exemplary purposes only.

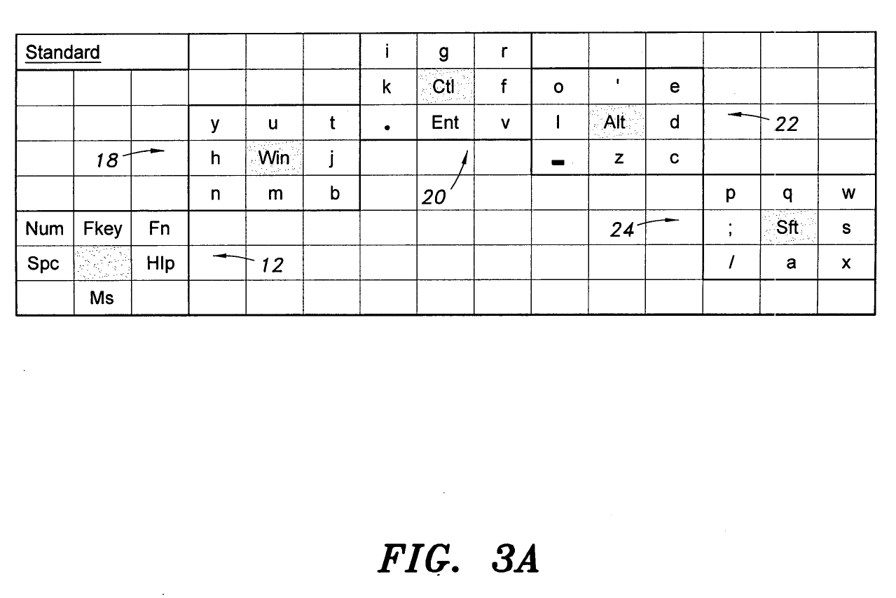

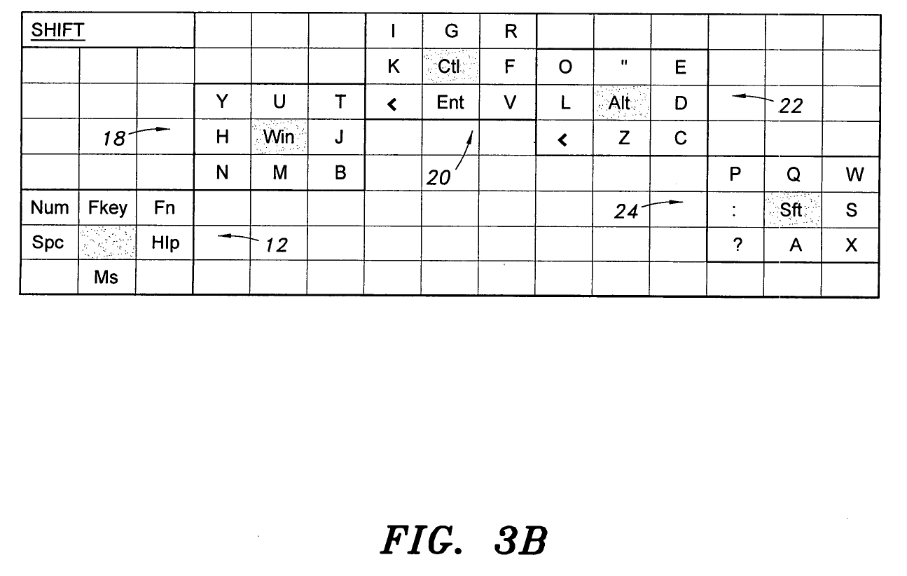

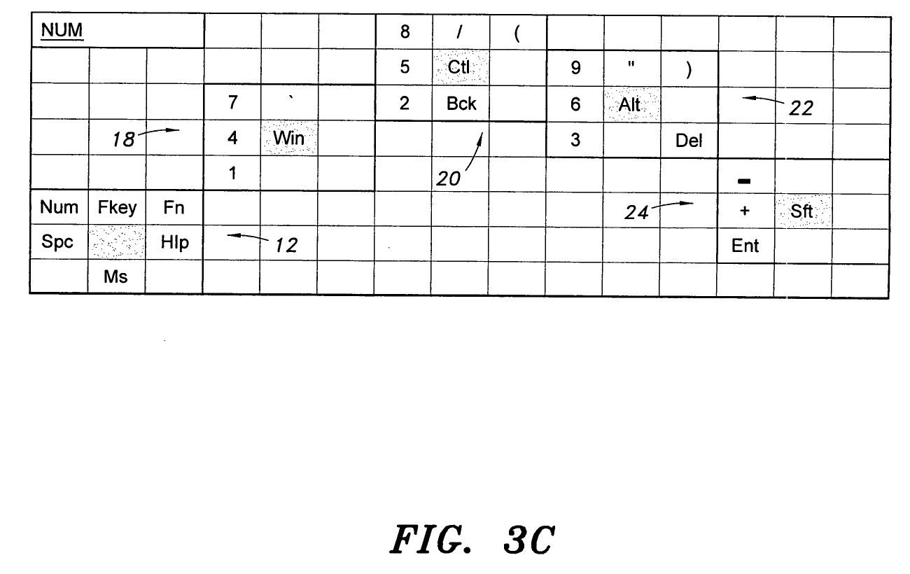

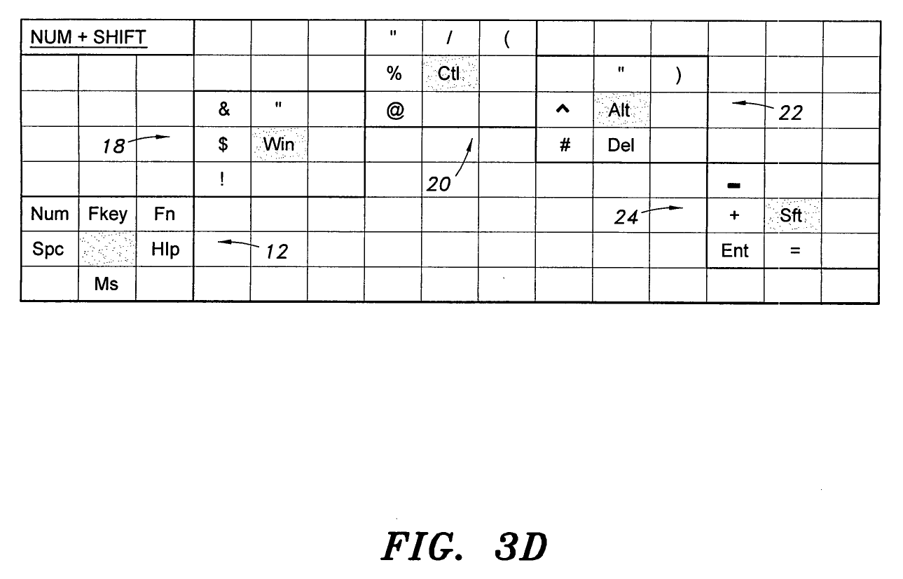

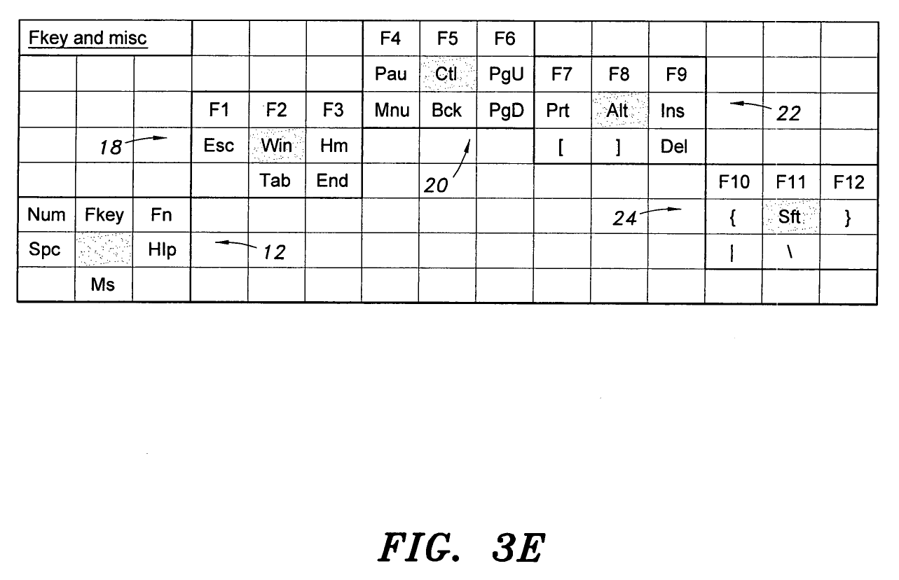

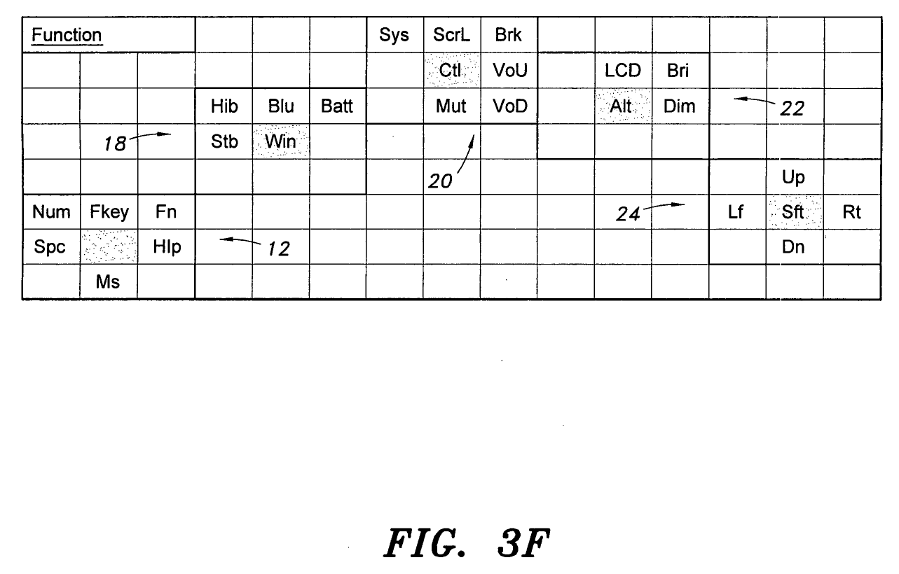

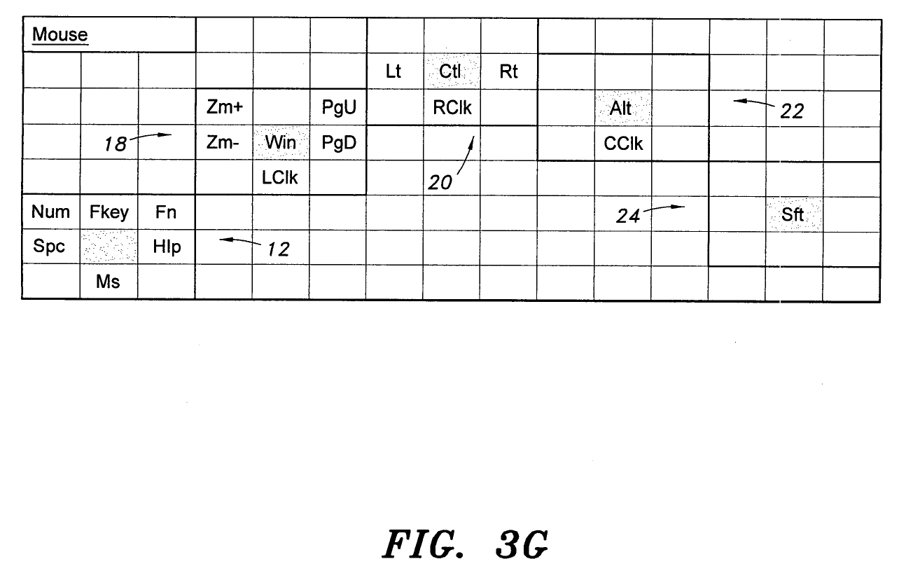

FIGS. 3A-3G illustrate in tabular form an exemplary correspondence of sensors 30, 32 with conventional computer characters and functions. In FIG. 3A, sensors 30 of finger regions 18, 20, 22, 24 represent standard character keys of a conventional keyboard, and in FIG. 3B, the “shift” central sensor 32 of pinkie finger region 24 has been actuated, with sensors 30 representing the conventional shifted character set (i.e., capital letters, etc.) of a conventional keyboard.

In FIG. 3C, the “Num” sensor of thumb region 12 has been actuated, thus causing sensors 30 of finger regions 18, 20, 22, 24 to represent the standard character set and functions of a conventional numeric keypad of a conventional computer keyboard. In FIG. 3D, the “Num” sensor of thumb region 12 and the “shift” central sensor 32 of pinkie finger region 24 have been actuated, thus assigning radially arrayed sensors 30 the character set associated with shifted number keys on a conventional keyboard (i.e., !, @, #, $, etc.)

In FIG. 3E, the “Fkey” sensor of thumb region 12 has been actuated, thus assigning the radially arrayed sensors of finger regions 18, 20, 22, 24 functions corresponding to the “F” function keys of a conventional keyboard (i.e., F1, F2, F3, etc.), and the miscellaneous function keys, such as “Insert”, “Delete”, “Page Up”, “Page Down”, etc. In FIG. 3F, the Fn sensor of thumb region 12 has been actuated, assigning the radially arrayed sensors of finger regions 18, 20, 22, 24 additional computer functions, such as setting the computer to “hibernate”, controlling speaker volume, dimming brightness of the associated computer display, representing directional control (e.g., up, down, left, right), etc.

In FIG. 3G, the “Ms” sensor of thumb region 12 has been actuated, allowing the interface device 10 to operate in a manner similar to that of a conventional mouse-type controller. Sensors 30 of index finger region 18 allow the user to zoom, scroll pages displayed on the screen up or down, and operate as a “left click”. Sensors 30 of middle finger region 20 allow the user to move a cursor (or other directional control) left or right, and operate as a “right click”. One sensor 30 of ring finger region 22 allows the user to operate a “center click” command. In FIG. 3G, the sensors 30 of pinkie finger region 24 remain unassigned. As noted above, sensors 30 and 32 may be assigned with any desired character set or set of functions.

Interface device 1 0 allows the user the full range of functionality of a conventional 104-key keyboard in addition to the functionality of a conventional mouse-type input device, but only requiring the user to use one hand, and further allowing the user to enter all input commands without moving his or her hand from one position. It should be understood that the specific examples given above are given for illustrative and exemplary purposes only. Alternate configurations of the key assignments, the number of sensors located within each finger region, the number of finger regions and the arrangement of the finger regions with respect to the housing, and the dimensions and contouring of the housing may all be varied without departing from the spirit and scope of the present invention. Similarly, though shown as a stand-alone unit, the interface device 10 may be incorporated or integrated into a separate device, a piece of computer hardware, a piece of furniture, or the like.

The one-handed configuration of interface device 10 is particularly useful in mitigating the causes of typical stress-related injuries, such as carpal tunnel syndrome, for example. Further, assigning a particular finger region for each finger and not requiring the user to move his or her fingers from this single position allows for great ease in training, and further allows for an increase in speed of usage, when compared to a conventional computer keyboard.

It is to be understood that the present invention is not limited to the embodiments described above, but encompasses any and all embodiments within the scope of the following claims.

I claim:

1. A one-handed computer interface device, comprising:
a housing having opposed upper and lower surfaces and at least one side surface, the lower surface being adapted for positioning on a support surface, the upper surface being divided into a plurality of finger regions, each of the finger regions being adapted for receiving one of a user's fingers; and
a plurality of sets of finger tip sensors, each of the sets being positioned within a corresponding one of the finger regions, respectively;
wherein actuation of one of the sensors generates a command signal corresponding to actuation of a computer input.

2. The one-handed computer interface device as recited in claim 1, wherein a thumb region is defined on the at least one side surface, the thumb region being adapted for receiving the user's thumb.

3. The one-handed computer interface device as recited in claim 2, further comprising a set of thumb tip sensors positioned within said thumb region.

4. The one-handed computer interface device as recited in claim 3, wherein each said set of finger tip sensors and said set of thumb tip sensors includes a plurality of radially arrayed sensors and a central sensor.

5. The one-handed computer interface device as recited in claim 4, wherein each of said finger regions and said thumb region include depressions for respectively receiving the user's fingers and the user's thumb.

6. The one-handed computer interface device as recited in claim 5, further comprising a scrolling controller disposed in said housing.

7. The one-handed computer interface device as recited in claim 6, wherein said scrolling controller comprises a scroll wheel.

8. The one-handed computer interface device as recited in claim 6, wherein indicia are formed on the upper surface and the at least one side surface adjacent the plurality of finger regions and the thumb region, the indicia indicating the corresponding computer input for each said finger tip and thumb tip sensor.

9. A one-handed computer interface device, comprising:
a housing having opposed upper and lower surfaces and at least one side surface, the lower surface being adapted for positioning on a support surface, the upper surface being divided into a plurality of finger regions, each of the finger regions being adapted for receiving one of a user's fingers, the housing having a thumb region defined on the at least one side surface, the thumb region being adapted for receiving the user's thumb; and
a plurality of sets of finger tip sensors and a set of thumb tip sensors, each of the sets of finger tip sensors being positioned within a corresponding one of the finger regions, respectively, the set of thumb tip sensors being positioned within the thumb region;
wherein actuation of one of the sensors generates a command signal corresponding to actuation of a computer input.

10. The one-handed computer interface device as recited in claim 9, wherein each said set of finger tip sensors and said set of thumb tip sensors includes a plurality of radially arrayed sensors and a central sensor.

11. The one-handed computer interface device as recited in claim 10, wherein each of said finger regions and said thumb region include depressions for receiving the user's fingers and the user's thumb, respectively.

12. The one-handed computer interface device as recited in claim 11, further comprising a scrolling controller disposed in said housing.

13. The one-handed computer interface device as recited in claim 12, wherein said scrolling controller comprises a scroll wheel.

14. The one-handed computer interface device as recited in claim 12, wherein indicia are formed on the upper surface and the at least one side surface adjacent the plurality of finger regions and the thumb region, the indicia indicating the corresponding computer input for each said finger tip and thumb tip sensor.

15. The one-handed computer interface device as recited in claim 14, wherein each said set of radially arrayed sensors comprises eight sensors.

16. A one-handed computer interface device, comprising:
a housing having opposed upper and lower surfaces and at least one side surface, the lower surface being adapted for positioning on a support surface, the upper surface being divided into a plurality of finger regions, each of the finger regions being adapted for receiving one of a user's fingers, the housing having a thumb region defined on the at least one side surface, the thumb region being adapted for receiving the user's thumb; and
a plurality of sets of finger tip sensors and a set of thumb tip sensors, each of the finger tip sets being positioned within a corresponding one of the finger region, the set of thumb tip sensors being positioned within the thumb region, each of the sets of finger tip sensors and the set of thumb tip sensors including a plurality of radially arrayed sensors and a central sensor;
wherein actuation of one of the sensors generates a command signal corresponding to actuation of a computer input.

17. The one-handed computer interface device as recited in claim 16, wherein each of said finger regions and said thumb region include depressions for respectively receiving the user's fingers and the user's thumb.

18. The one-handed computer interface device as recited in claim 17, further comprising a scrolling controller.

19. The one-handed computer interface device as recited in claim 18, wherein indicia are formed on the upper surface and the at least one side surface adjacent the plurality of finger regions and the thumb region, the indicia indicating the corresponding computer input for each said finger tip and thumb tip sensor.

20. The one-handed computer interface device as recited in claim 19, wherein said set of thumb tip sensors corresponds to computer function keys.
